(19) United States
(12) Patent Application Publication
(10) Pub. No.: US 2025/0246580 A1
(43) Pub. Date: Jul. 31, 2025

(54) INTEGRATED CIRCUIT DIE STACK WITH A BRIDGE DIE

(71) Applicant: Advanced Micro Devices, Inc., Santa Clara, CA (US)

(72) Inventors: Arsalan ALAM, Austin, TX (US); Chandra Sekhar MANDALAPU, Lehi, UT (US); Liwei WANG, Austin, TX (US); Manish DUBEY, Austin, TX (US)

(21) Appl. No.: 18/429,117

(22) Filed: Jan. 31, 2024

(51) Int. Cl. H01L 25/065; H01L 23/00; H01L 23/528; H01L 23/64; H01L 25/00

(52) U.S. Cl. CPC H01L 25/0652; H01L 23/528; H01L 23/562; H01L 23/642; H01L 24/08; H01L 25/50; H01L 2224/08145

(57) ABSTRACT

Disclosed herein are an integrated circuit die stack and an integrated circuit die package assembly having the integrated circuit die stack. The integrated circuit die stack includes a plurality of integrated circuit dice disposed in a first tier of the die stack and a plurality of integrated circuit dice disposed in a second tier of the die stack. The plurality of integrated circuit dice of the second tier are stacked vertically above the plurality of the integrated circuit dice of the first tier and include a bridge die. The bridge die couples with at least two dice of the first tier and includes an integrated passive device coupled with a routing connection.

### TECHNICAL FIELD

Embodiments of the present invention generally relate to an integrated circuit die stack with a bridge die, and, more particularly, relate to an integrated circuit die stack with a bridge die capable of providing lateral communication for integrated circuit dice at a lower tier.

### BACKGROUND

Electronic devices, such as tablets, computers, copiers, digital cameras, smart phones, control systems and automated teller machines, among others, often leverage chip package assemblies for increased functionality. To increase processing capabilities, chip packaging schemes often form a die stack by vertically mounting a plurality of integrated circuit dice to a package substrate. The integrated circuit die stack may include integrated circuit dice for memory, logic, communication, power management, or other functions.

In an integrated circuit die stack, integrated circuit dice of the same tier or different tiers often need to communicate with each other at a high speed and with high integrity. The current designs of die stacks have not provided effective solutions for such high speed and high integrity lateral communications.

Therefore, a need exists for an improved integrated circuit die stack.

### SUMMARY

Disclosed herein are an integrated circuit die stack and an integrated circuit die package assembly having the integrated circuit die stack. The integrated circuit die stack includes a plurality of tier-one integrated circuit dice disposed at a first tier of the die stack and a bridge die disposed at a second tier of the die stack. The bridge die of the second tier are stacked vertically above the plurality of the tier-one integrated circuit dice of the first tier. The bridge die couples with at least two tier-one integrated circuit dice of the first tier. The bridge die includes an integrated passive device coupled with at least a routing connection.

According to an embodiment, the integrated circuit die package assembly includes a package substrate; and an integrated circuit die stack coupled with the package substrate. The integrated circuit die stack includes a first integrated circuit die and a second integrated die disposed at a first tier of the die stack; and a bridge die as set forth in the present disclosure and disposed at a second tier that is stacked vertically above the first tier. The bridge die includes an integrated passive device coupled with at least a routing connection. The bridge die couples the first integrated circuit die to the second integrated circuit die via the routing connection.

A method for manufacturing an integrated circuit die stack comprising a plurality of tiers of dice. The method includes mounting a plurality of dice of a first tier on a carrier; arranging a plurality of dice of a second tier on top of the dice of the first tier, the plurality of the dice of the second tier comprising a bridge die as set forth in the present disclosure; forming an integrated circuit die stack by connecting the dice of the first tier with the dice of the second tier, wherein the connecting comprises connecting the bridge die with at least two dice of the first tier; and mounting the integrated circuit die stack die stack on a package substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1a illustrates a schematic cross-sectional view of an electronic device having an integrated circuit die stack with a bridge die according to an embodiment of the present application.

FIG. 1b illustrates a schematic top view of an IC die stack, according to an embodiment of the present application.

FIG. 2a illustrates a schematic close-up view of an IC die stack having two tiers of IC dice, according to an embodiment of the present application.

FIG. 2b illustrates a schematic configuration of an IC die stack having three tiers of IC dice, according to an embodiment of the present application.

FIG. 2c illustrates a schematic configuration of an IC die stack comprising a bridge die and an electronic device, according to an embodiment of the present application.

FIG. 3a is a schematic cross-sectional view of a bridge die having a passive device according to an embodiment of the present application.

FIG. 3b illustrates a schematic cross-sectional view of another bridge die having a passive device, according to an embodiment of the present application.

FIG. 3c illustrates a schematic cross-sectional view of another bridge die having an active device, according to an embodiment of the present application.

FIG. 4 illustrates a schematic manufacturing process for making an IC die stack having a bridge die, according to an embodiment of the present application.

FIG. 5 illustrates a method for manufacturing an IC die stack having a bridge die, according to an embodiment of the present application.

To facilitate understanding, identical reference numerals have been used, where possible, to designate identical elements that are common to the figures. It is contemplated that elements of one embodiment may be beneficially incorporated in other embodiments.

### DETAILED DESCRIPTION

An integrated circuit die stack is disclosed that includes a bridge die for lateral communication among dices of a lower tier. The bridge die may include passive devices, such as capacitors, adjacent to the input and/or output routings of the bridge die. When placed directly under the routings of the bridge die, the integrated passive devices forms a clean path with the routings and effectively improve the power and signal integrity of the routings. The bridge die may also include active devices, such as active circuitries. The bridge die includes a redistribution layer built up on a surface of a substrate, such as silicon, glass, or any other suitable substrate. The redistribution layer couples with other integrated circuit dice disposed in a lower tier via a plurality of hybrid bonds. Pitches of the hybrid bonds are denser than connections made by wire bonds or micro solder balls, thus enabling high density, high speed data transmission. Further, the bridge die shortens routing distances between IC dice within the IC die stack, thus increasing processing speeds while advantageously improving signal integrity. The integrated passive and/or devices, such as a capacitor and an active circuitries, may be included in the redistribution layer.

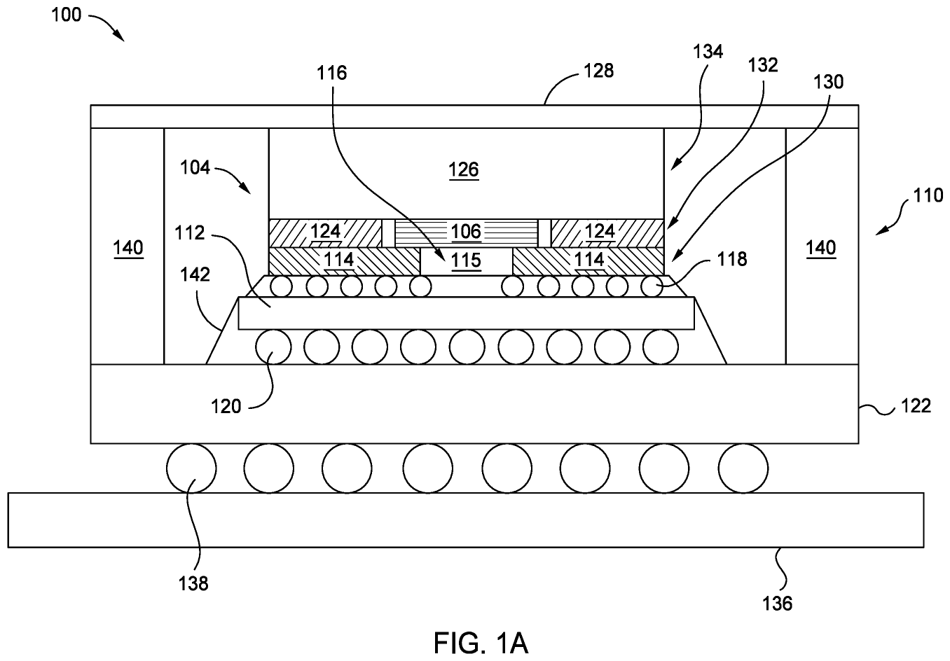

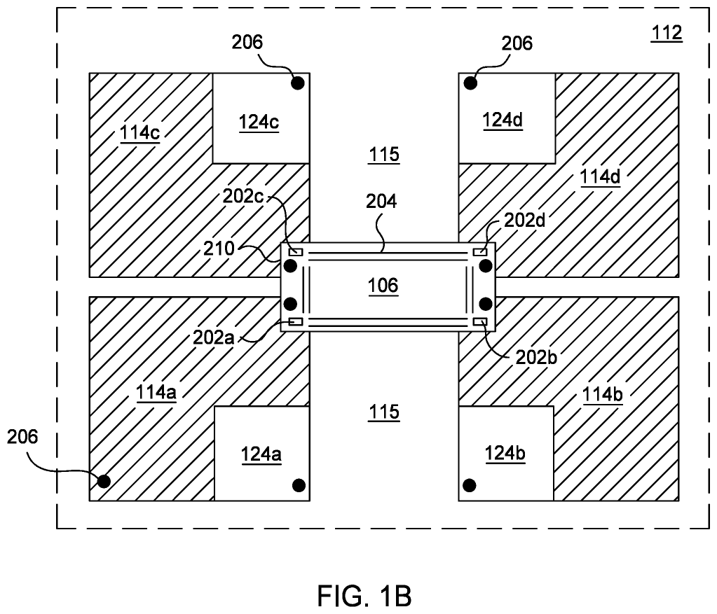

Turning now to FIG. 1a, an exemplary integrated circuit (IC) die package assembly 110 is disposed on a printed circuit board (PCB) 136 and is connected with the PCB 136 via a plurality of electric connections 138, such as solder balls or other suitable connections. The IC die package assembly 110 and the PCB 136 together form at least part of an electronic device 100. The electronic device 100 may be a tablet, computer, copier, digital camera, smart phone, control system, automated teller machine, server or other solid-state memory and/or logic device.

The IC die package assembly 110 includes an IC die stack 104 mounted to an optional interposer 112. According to an embodiment, the IC die stack 104 may be mounted directed to a package substrate 122. The IC die package assembly 110 further includes an optional stiffener 140 coupled with the package substrate 122 and configured to enhance the warpage resistance of the package substrate 122 against out of plane deformation. The IC die package assembly 110 further includes a lid 128 configured to cover the IC die stack 104 and dissipate heats generated by the IC die package assembly 110.

The IC die stack 104 includes a plurality of tiers of IC dice stacked vertically on top of each other. For example, three tiers of IC dice are shown in FIG. 1a: a first tier 130, a second tier 132, and a third tier 134. The IC dice of a same tier are configured to be substantially co-planar with each other. According to an embodiment, the IC die stack 104 is not limited to just three tiers of IC dice and may include four (4), five (5), or even a greater number of tiers of IC dice. IC dice disposed at the first tier 132 include two IC dice 114. The IC dice 114 at the first tier 130 may be directly coupled with the interposer 112 or the package substrate 122. Connections among the IC dice of the plurality of tiers may include solder balls, microbumps, thermal compression bonds, hybrid bonds, through silicon vias (TSV), or another other suitable connections.

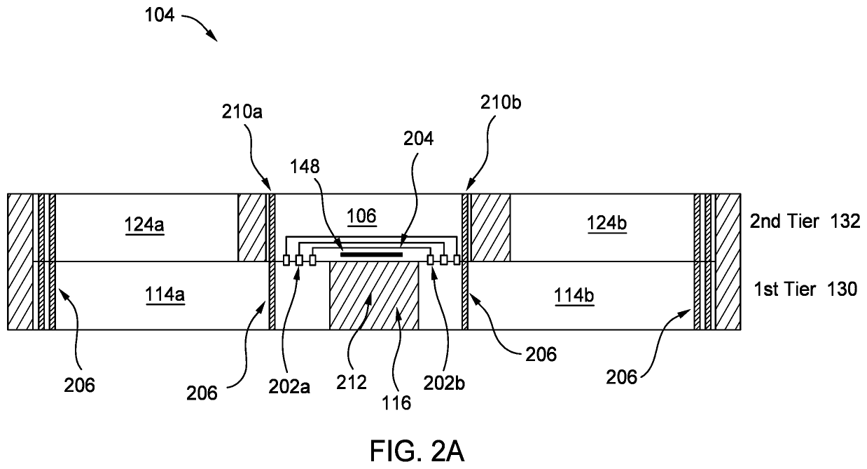

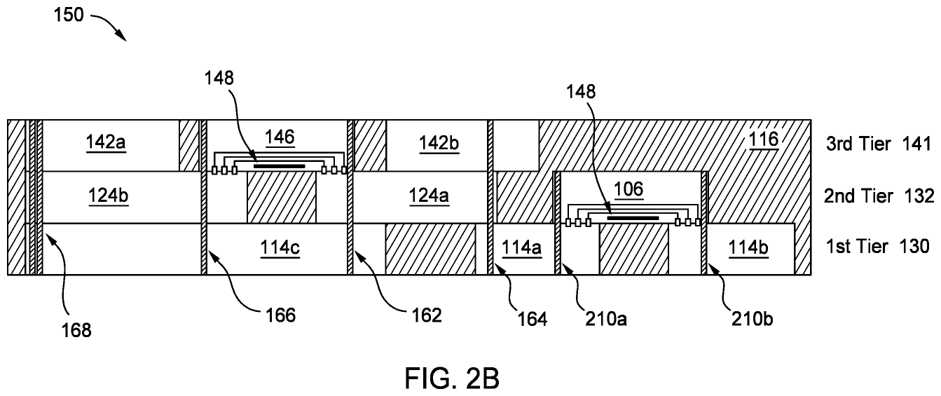

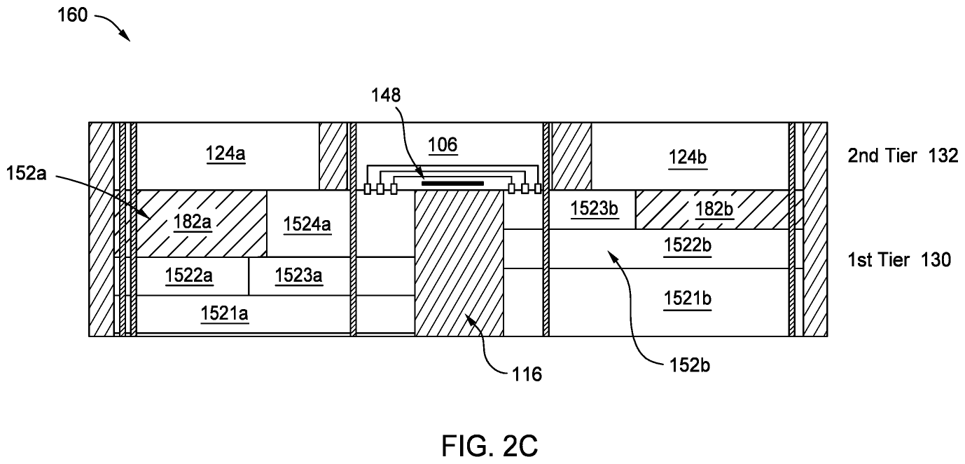

As shown in FIG. 1a, two IC dice 124 and a bridge die 106 are disposed at the second tier and stacked vertically above the IC dice 114. According to an embodiment, the two IC dice 114 in the lower tier are configured to communicate with each other via the bridge die 106 disposed at the second tier 132. The two IC dice 114 may also communicate with each other via the interposer 112. According to an embodiment, the bridge die 106 includes a plurality of integrated passive and/or active devices (show as 148 in FIG. 2a), such as capacitors, inductors, and active circuitries. For example, the bridge 106 may include a capacitor integrated into a buildup layer at a location directly under the routing connections. A capacitor can be made in the buildup layer by various methods, such as deep trench capacitors, Metal-Insulator-Metal (MIM) capacitors (MIMCAP). When coupled directly with the routing connections, the integrated passive devices can effectively improve power and signal integrity of the routing connections.

The number of IC dice disposed of each tier is not limited to two (2) or three (3) dice as shown in FIG. 1a. Each tier may include a greater number of IC dice, such as four (4), six (6), ten, or even a greater number of dice. Each tier may include a single die, an IC die stack, or a combination thereof.

FIG. 1a also illustrates relative dimensions of IC dices in different tiers, according to an embodiment. The length of each die is shown in a horizontal direction, while the height of each die is shown in a vertical direction. In one example, the bridge die 106 disposed at the second tier 132 couples with IC dice 114 of the first tier 130. As a result, the length of the bridge die 106 is greater than the length of the gap 115 formed among the IC dice 114. Each IC dice 114 couples with both the bridge die 106 and another IC die 124 at a higher tier. In an example, the length of the top surface of the IC die 114 is configured to be greater than the length of the bottom surface of the IC die 124, such that the bottom surface of the IC die 124 is entirely mounted on the top surface of the IC die 114. Thus, each of the IC dice 114 may have a larger size than the IC dice 124. For example, the IC die 114 has a top surface area (length×width) that is greater than a bottom surface of the IC die 124.

In one embodiment, the bridge die 106 and the IC dice 124 are coupled to the IC dice 114 via a plurality of hybrid bonds. The bridge die 106 is configured to provide a high speed and high integrity data transmission between the two IC dice 114 disposed at the first tier 130.

In the exampled depicted in FIG. 1a, the third tier 134 includes a filler die 126 configured to fill the space between the second tier 132 and the lid 128. The filler die 126 is configured to raise the height of the IC die stack 104 to the same height as the stiffener 140. The filler die 126 may include a semiconductor substrates, such as a silicon substrate. In one example, the filler die 126 forms a non-conductive contact with the dice 124 and is not electrically connected to the dice 124. Again, the IC die stack 104 is not limited to only three tiers. A greater or lesser number of tiers of IC dice may be included in the IC die stack 104. In addition, a greater or less number of IC dice may be included in each tier. In another example, the third tier 132 may include a plurality of IC dice, which may include a bridge die.

The IC dice 114 and 124 may be programmable logic devices, such as field programmable gate arrays (FPGA), memory devices, optical devices, processors or other IC logic structures. The interconnection among IC dice of different tiers may include TSVs, hybrid bonds, or micro solder balls. The IC die stack 104 mounted to a top surface of the interposer 112 by die connections 118. The die connections 118 may be in the form of a plurality of solder joints, also known as “micro-bumps.”

The interposer 112 includes a circuitry for electrically connecting the IC die stack 104 to a circuitry of the package substrate 122. Solder connections 120, also known as or “package bumps” or “C4 bumps,” are utilized to provide an electrical connection between the circuitry of the interposer 112 and the circuitry of the package substrate 122. The package substrate 122 may be mounted and connected to the PCB 136, utilizing solder balls 138, wire bonding or other suitable technique.

An under molding 142 may be utilized to fill the space not taken by the solder connections 120 between the PCB 136 and the interposer 112 or the package substrate 122. A gap fill material 116 may be utilized to fill gaps within the IC die stack 104.

FIG. 1b illustrates a schematic top view of the IC die stack 104, according to an embodiment. A plurality of IC dice are mounted on the interposer 112. The IC dice 114a, 114b, 114c, and 114d are arranged at the first tier 130. The IC dice 124a, 124b, 124c, and 124d are arranged at the second tier. The bridge die 106 are arranged at the same tier as the IC dice 124a, 124b, 124c, and 124d. The IC dice are separated by the gaps 115. The IC dice 114a, 114b, 114c, and 114d may communicate with each other via the interposer 112 and/or the bridge die 106. The IC dice 114a, 114b, 114c, and 114d of the first tier couple with a plurality of IC dice of the second tier 124a, 124b, 124c, and 124d. For example, the IC dice 124a, 124b, 124c, and 124d are mounted on top surfaces of the IC dice 114a, 114b, 114c, and 114d, respectively. The IC dice 124a, 124b, 124c, and 124d are not directly connected with the bridge die 106.

In an embodiment, IC dice 114a-d of the first tier are also coupled with the bridge die 106 to have a high speed and high integrity communication. As shown in FIG. 1b, a portion of each of the IC dice 114a-d are disposed under and overlaps with a portion, such as a corner, of the bridge die 106. Hybrid bonds 202a-d electrically and mechanically connect the overlapped portions of the IC dice 114a-d and the bridge die 106 to enable communication therebetween. The IC die 104a may communicate with any of the IC dice 114b, 114c, and 114d via the bridge die 106. The bridge die 106 is capable of providing a faster and more robust data communication than the interposer 112. While an IC die of conventional packages would need to be routed vertically down to a substrate then back up for a communication with another die, the bridge die 106 shortens the routing distances between dice on the same tier, thus improving processing performance and signal integrity.

As discussed above, the bridge die 106 couples with the plurality of IC dice 114a-d via the hybrid bonds 202a-d. The hybrid bonds includes metal-to-metal bonds formed by a hybrid bonding process. For example, the metal-to-metal bonds may be formed using pressure and heat to form eutectic metal bonds. A hybrid bond may be formed by bonding the dielectric materials surrounding bond pads to first secure IC dice, followed by an interfusion of the metal materials of the bond pads to create the electric interconnect. The dielectric materials surrounding the bond pads is selected from a material suitable for hybrid bonding to another dielectric material. Materials that are suitable for hybrid bonding include polybenzoxazole (PBO), polyimide (PI), benzocyclobutene (BCB), a combination thereof, or the like. According to an embodiment, the pitch among the hybrid bonds 202a-d is less than 10 μm, 5 μm, or 1 μm. The hybrid bonds of the bridge die 106 provides a significantly denser pitch of connections than wire bonds or micro solder balls. As a result, the communication bandwidth between the hybrid bonded IC dice 114a and 114b is significantly greater than conventional devices.

In an embodiment, the hybrid bonds 202a-d of the bridge die 106 couple with each other via a plurality of routing connections 204. The plurality of routing connections 204 may include metal traces formed in a buildup layer. The routing connections 204 terminate at the hybrid bond pads that are configured to form one side of the hybrid bonds 202. In one example, at least one of the routing connections 204 is configured to provide high speed and high integrity data transmission between the two IC dice 114 disposed at the first tier 130, or other tier of the chip package.

As shown in FIG. 1b, the IC dice may include a plurality of through silicon vias (TSVs), such as TSVs 206 and TSVs 210. For example, TSVs 206 connect the IC dice 114a-d of the first tier with IC dice 124a-d of the second tier. The TSVs 206 can also provide vertical connectivity between the interposer 112 and the IC dice. The TSVs 206 may transfer several types of signals, including power, ground connection, data signal, testing signals, control signal, timing signal, encryption signal, or any other signals transmitted from a die to another die. TSVs 210 connect the bridge die 106 with the dice 114a-d of the first tier. The TSVs 210 may provide similar electric connections as the TSVs 210. The TSVs 210 and 206 may couple with each other to provide electrical connection between the bridge die 106 and the circuitry of the dice 114 or the interposer 112. Having TSVs 210 in the bridge die 106 increases design flexibility as vertical connections among IC dices in different tiers can be additionally routed through TSVs of the bridge die. Stated differently, the ability to used TSVs 210 in addition to TSVs 206 enables greater flexibility in locating power, ground and signal transmission routing, which ultimately improves signal integrity and device performance.

FIG. 2a illustrates a schematic configuration of the first and second tiers of the IC die stack 104, according to an embodiment. As described above, the bridge die 106 is disposed at the second tier 132 and coupled with two dice 114a and 114b disposed at the first tier 130. The bridge die 106 includes an integrated passive device 148, such as a capacitor. The integrated passive device is placed adjacent to and electrically connected with the routing connections 204, thereby providing an effective and clean path to improve power and signal integrity routed through the bridge die 106. In an example, the bridge die 106 directly overlays and couples to the dice 114a and 114b. The IC dice 114a and 114b may have a larger size than the IC dice 124a and 124b. As a result, the IC die 124a is disposed entirely on the top surface of the IC die 114a. Since the IC die 114a is larger than the IC die 124a, the IC die 114 has enough space available for routings needed to establish high density interconnects between the IC die 114a and the bridge die 106. The same is true regarding the IC dice 114b and the bridge die 106. According to an embodiment, the bridge die 106 and the dice 124a and 124b are coupled via a plurality of hybrid bonds 202a and 202b.

According to an embodiment, a gap 212 between the die 114a and the die 114b is filled with a gap fill material 116, such as a dielectric material. The gap fill material 116 also fills other gaps formed among the IC dice disposed at the first tier and the second tier. The die 114a at the first tier is not limited to couple with only 2 dice at the second tier. The die 114a may couple with 3, 4, or 5 IC dice at the second tier. According to an embodiment, at least one die at the second tier that couples with the dice 114 is configured to be a bridge die that provides lateral data communication among the dice 114 and other dice disposed at the first tier.

According to an embodiment, the die 124a couples with the die 114a via any suitable connections, such as hybrid bonds, micro solder balls, or other solder interconnect. The dice 114a and 114b may also include a plurality of TSVs 206 that couple with the dice 124a and 124b. The bridge die 106 may also include TSVs 210a and 210b that couple with the TSVs 206. For example, a TSV 210a of the bridge die 106 is coupled with a TSV 206 of the IC die 114a to form a vertical connection, which may be used to provide power, ground connection, or test signal.

FIG. 2b illustrates a schematic configuration of an IC die stack 150, according to an embodiment. The IC die stack 150 includes three (3) tiers of IC dice 130, 132, and 141, respectively. One or more additional tiers of IC dice may be disposed among the first, second, and third tiers. The present application may include additional tiers, such as a 4^{th} tier of IC dice. A bridge die may be disposed in each tier of IC dice and configured to provide interconnection among IC dice at a lower tier. For example, bridge dice are disposed at the 3^{rd} and 2^{nd} tiers to provide interconnection among dice at the 2^{nd} and 1^{st} tier, respectively.

As shown in FIG. 2b, the first tier 130 includes IC dice 114a, 114b, and 114c and does not include a bridge die. The second tier 132 includes a bridge die 106, an IC dice 124a and 124b. The bridge die 106 couples with both the IC dice 114a and 114b to provide lateral communication therebetween. An integrated passive device 148 is placed in the bridge die 106 to improve power and signal integrity of the routing connections. TSVs 210a and 210b provide vertical connections between the bridge die 106 and the IC dice 114a and 114b. The IC die 124b is mounted on top surfaces of IC dice 114a and 114c. The IC die 124b communicate with the IC dice 114c and 114a via TSVs 162 and 164, respectively. Other connections, such as hybrid bonds, BOEL, or microbumps, are also provided between the IC die 124b and IC dice 114c and 114a. The IC die 124a is mounted on the top surface of the IC die 114c. TSVs 168 and 166 and other connections, such as hybrid bonds, BOEL, or microbumps, may be provided between the IC die 124a and the IC die 114c.

The 3^{rd} tier 141 includes a plurality of IC dice 142a and 142b and a bridge die 146. The IC die 142a is mounted on the top surface of the IC die 124a. TSV 168 and other connections, such as hybrid bonds, BOEL, or microbumps, provides vertical connections among the IC dice 142a, 124a, and 114c. The bridge die 146 couples with both the IC dies 124a and 124b and is configured to provide data communication therebetween. An integrated passive device 148 is placed in the bridge die 146 to improve power and signal integrity of the routing connections. TSVs 166 and 162 and other connections, such as hybrid bonds, BOEL, or microbumps, provide vertical connection among the bridge die 106 and the IC dice 124a, 124b, and 114c. The IC die 142b is mounted on a top surface of the IC die 124b. TSV 162 provides vertical connection among the IC dice 142b, 124b, and 114c.

FIG. 2c illustrates a schematic configuration of an IC die stack 160, according to an embodiment. The IC die stack 160 has two tiers 130 and 132, similar with that of the IC die stack 104 shown in FIG. 2a. Comparing to the dice 114a and 114b in FIG. 2a, the IC die stack 160 may include another die stack(s) in one or more tiers. For example, the first tier 130 includes two die stacks 152a and 152b functioning as an electronic device with a set of predetermined functions. Stated differently, the IC die 114a in FIG. 2 is replaced by the electronic device 152a, and the IC die 114b in FIG. 2 is replaced by the electronic device 152b. Both electronic devices 152a and 152b are IC die stacks. For example, the device 152a includes four (4) IC dice 1521a, 1522a, 1523a, and 1524a stacked on top of each other, in which the die 1524a is connected with the bridge die 106. The bridge die 106 also has an integrated passive device 148, such as a capacitor, to improve power and signal integrity of the routing connections. The device 152b includes three IC dice 1521b, 1522b and 1523b stacked on top of each other, in which the IC die 1523b is connected with the bridge die 106. As shown in FIG. 2c, the top surfaces of the IC dice 1524a and 1523b are substantially coplanar such that they can be coupled with the bridge die 106. When the devices 152a and 152b may not have a similar height, a molding compound 182a may be utilized to fill the space within the stack 152a defined between IC die 1522a and 124a. Similarly, a molding compound 182b may also be utilized to fill the space within the stack 152b defined between IC die 1522b and 124b. The molding compound 182a and 182b may be silicon, resin, or epoxy based plastics.

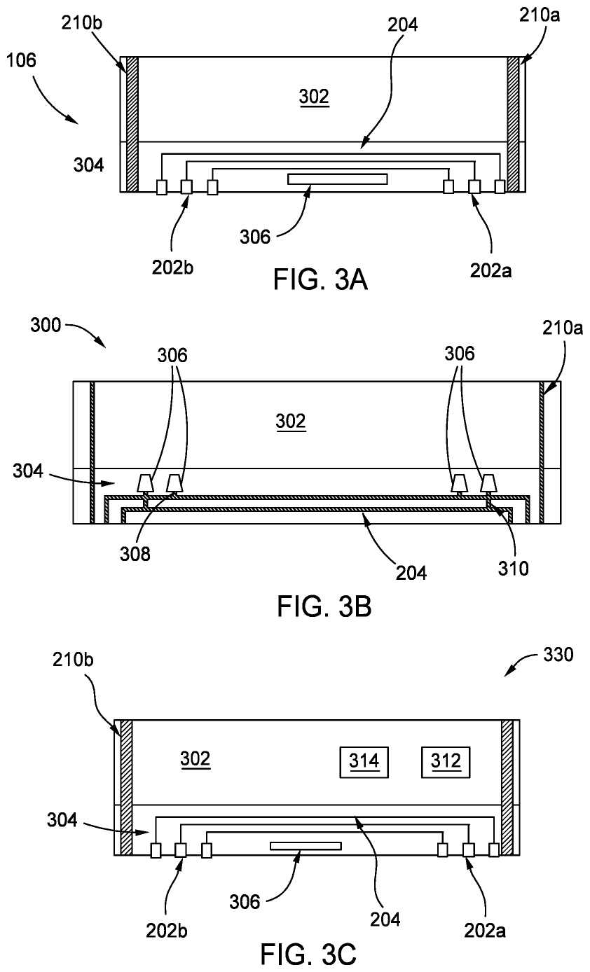

FIG. 3a illustrates a schematic cross-sectional view of a bridge die 106, according to an embodiment. The bridge die 106 includes a substrate 302 and a buildup layer 304. The substrate 302 may be a silicon substrate, a glass substrate, a silicon carbide substrate, a germanium substrate, or other suitable substrate. The buildup layer 304 may also be known as a redistribution layer (RDL). The buildup layer 304 includes two or more metal layers that are patterned for form metal routings that define the routing connections 204. Dielectric layers are disposed between the metal layers to prevent shorting between the routing connections 204. The routing connections 204 terminate at the hybrid bond pads used to form one side of the hybrid bonds 202a and 202b electrically and mechanically coupling the routing connections 204 of the bridge die 106 to the bond pads and functional circuitry of the other dice 124, 114.

According to an embodiment, one or more passive devices 306, such as capacitors, inductors, resistors, sensors, transducers, circuit protection devices, piezoelectric devices, resonators, switches, and the like, may also be integrated in the buildup layer 304 to improve power or signal integrity. In an example, the integrated passive device 306 functions as a capacitor. For example, a passive device 306 formed in the buildup layer 304 may be configured as a deep trench capacitor, a Metal-Insulator-Metal (MIM) capacitor (MIMCAP) or other type of capacitor. A capacitor may be readily made by a few metal and dielectric layers and will not substantially increase the thickness of the buildup layer 304. When placed adjacent to the routing connections 204, such as directly under or above the routing connections 204, the integrated passive device 306 can effectively improve power and signal integrity of the routing connections 204. The passive devices 306 are coupled by the routing connections 204 to one or both of the dice 124, 114 connected to the bridge die 106.

FIG. 3b illustrates a schematic cross-sectional view of a bridge die 300, according to an embodiment. The bridge die 300 includes a plurality of integrated passive devices 306 disposed adjacent to the routing connections 204. In an embodiment, the plurality of integrated passive devices 306 include capacitors distributed along the routing connections 204. The capacitors are formed in the buildup layer 304 under the routing connections 204. In one example, a first connection 308 couples a first routing of the routing connections 204 with the integrated passive devices 306. The first routing of the routing connections 204 routing connections 204 may also be coupled by a second connection 310 at locations adjacent to the integrated passive devices 306. In this way, one integrated passive device 306 may be shared by a plurality of routing connections 204. In other examples, none of the integrated passive devices 306 are shared by a common routing connections 204. In one example, a routing connections 204 coupled with a integrated passive device 306 is configured to provide high speed and high integrity data transmission between the two IC dice 114 disposed at the first tier 130, or other tier of the chip package. The first connections 308 and the second connections 310 are formed by metal layers and/or vias formed in the buildup layer 304.

FIG. 3c illustrates a schematic cross-sectional view of a bridge die 330 having one or more integrated active devices, according to an embodiment. The bridge die 330 includes one or more active devices 312 and 314 in the substrate 302. Some examples of active devices 312 and 314 include diodes, rectifiers, varactors, transistors, thryistors and the like. In an embodiment, the active devices 312 and 314 may function as a memory controller circuitry, including an on-package memory controller 312 and an off-package memory controller 314. The on-package memory controller circuit 312 is configured to control memories disposed within the package 110. The off-package memory controller circuitry 314 is generally configured to control communications with memory that is not within (e.g., remote from) the chip package 110. In one example, the off-package memory controller circuitry 314 is configured to communicate through the package substrate with the one or more memory devices that are mounted to the PCB; or stated differently, memory devices that are located within the electronic device 100 but are not within the chip package 110. The active devices 312 and 314 may be formed within the substrate 302 of the bridge die 330. In addition to the active devices 312 and 314, the bridge die 330 may also include one or more passive device 306.

In one example, the memory controller circuitry 312 and 314 include one or more of active circuitries, such as interconnect circuitry, high bandwidth memory attached last level cache (HALL) circuitry, tag circuitry, memory circuitry, memory controller circuitry, memory devices, and direct memory access (DMA) circuitry. The silicon bridge 330 may include coherency station circuitry that includes N coherency station circuitries. The HALL circuitry includes N HALL circuitries, the tag circuitry includes N tag circuitries, and the memory controller circuitry includes N memory controller circuitries. N is greater than 1. In one example, N is 2, 4, or 8, or more.

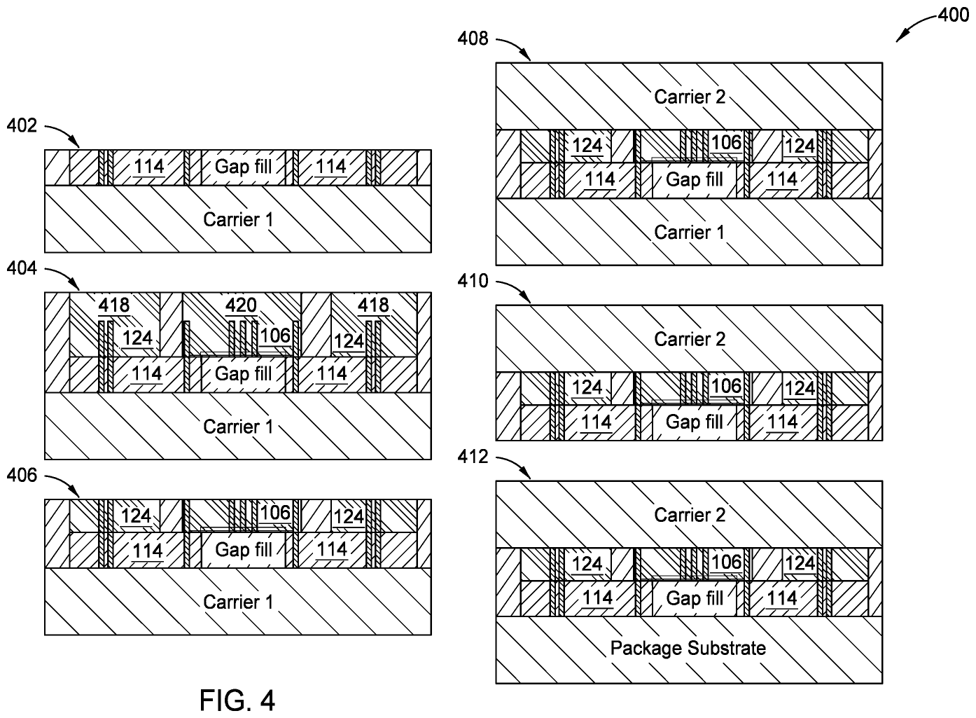

FIG. 4 is a schematic manufacturing process 400 for making an IC die stack according to an embodiment of the present application. Before operation 402, the dice 114 and 124 and the bridge die 106 have been fabricated with known techniques. As the dice 114, 124 and the bridge die 106 may be made of different techniques, the dice 114, 124 and the bridge die 106 may have different heights. According to an embodiment, the dice 124 and the bridge die 106 are disposed at the same tier and include certain depths of spare materials 418 and 420, respectively. The spare materials 418 and 420 have no electrical traces or devices and are designed to be removed by proper methods, such as grinding, milling, or other processes. The spare materials 418 and 420 are disposed at an inactive side of the dice 124 and the bridge die 106.

At operation 402, the dice 114 are mounted to a No. 1 carrier to form the first tier of IC dice. The No. 1 carrier may be made of any material that can support dice in a chip making process, such as a silicon substrate or any other suitable substrates. A gap fill material 116 is deposited in the gaps among the dice 114.

At operation 404, the dice 124 and the bridge die 106 are mounted on top of the dice 114. Connections between the bridge die 106 and the dice 114 are formed. More gap fill materials 116 are deposited to secure the dice 124 and the bridge die 106.

At operation 406, the spare materials 418, 420 and the gap fill material 116 are removed by proper methods, such as grinding, milling, or any other suitable techniques. As a result, the dice 124 and the bridge die 106 have a similar height and the TSVs are exposed. Operation 406 forms the second tier of IC dice.

Operations 404 and 406 may be repeated to include additional tiers of IC dice. Each tier may optionally include a bridge die configured to provide lateral communications for IC dice at a lower tier.

At operation 408, a No. 2 carrier is mounted on the dice 124 and the bridge die 106 at a side opposite to the No. 1 carrier. The No. 2 carrier may be made of a material similar to that of the No. 1 carrier.

At operation 410, the No. 1 carrier is removed, thus exposing the bottom surface of the dice 114 at the first tier.

At operation 412, the No. 2 carrier and the dice are mounted on a package substrate, an interposer, or another substrate, which couples the communication interface of IC dice of the first tier with another electrical component.

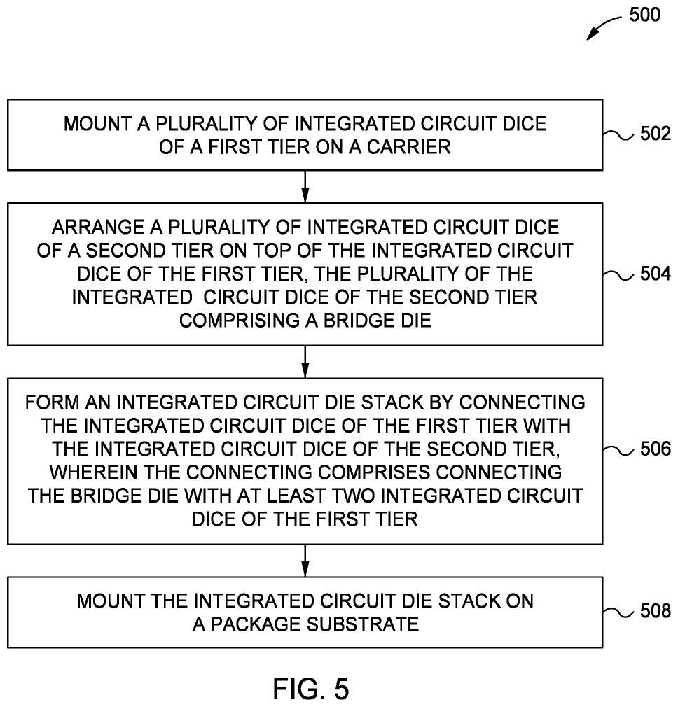

FIG. 5 illustrates a method of manufacturing an integrated circuit die stack according to an embodiment of the present application. At operation 602, a plurality of IC dice of a first tier are manufactured. At operation 604, a plurality of IC dice of a second tier are manufactured. The plurality of IC dice of the second tier include a bridge die. At operation 606, the plurality of the dice of the first tier are arranged on a carrier. At operation 608, the plurality of the dice of the second tier are arranged on top of the dice of the first tier to form an integrated circuit die stack. During the arrangement of the dice of the second tier, the bridge die of the second tier connects with at least two dice of the first tier. The dice of the second tier may be collectively arranged on the first tier by using a common carrier or may be individually arranged. At operation 610, the integrated circuit die stack die stack is mounted on a package substrate.

While the foregoing is directed to embodiments of the present invention, other and further embodiments of the invention may be devised without departing from the basic scope thereof, and the scope thereof is determined by the claims that follow.

What is claimed is:

1. An integrated circuit die stack comprising:
a plurality of tier-one integrated circuit dice disposed at a first tier of the integrated circuit die stack:
a bridge die disposed at a second tier of the integrated circuit die stack and stacked vertically adjacent with the plurality of the tier-one integrated circuit dice of the first tier, the bridge die including routing connection coupled with at least two tier-one integrated circuit dice; and
an integrated passive device disposed in the bridge die and coupled with the routing connection.

2. The integrated circuit die stack of claim 1, wherein integrated passive device is one of a capacitor, an inductor, a resistor, a sensor, a transducer, a circuit protection device, a piezoelectric device, a resonator, or a switch.

3. The integrated circuit die stack of claim 2, wherein the routing connections are coupled by a plurality of hybrid bonds of the at least two tier-one integrated circuit dice.

4. The integrated circuit die stack of claim 3, wherein a pitch of the hybrid bonds is less than 10 μm.

5. The integrated circuit die stack of claim 1, wherein the routing connection is defined by a redistribution layer (RDL) formed on a substrate.

6. The integrated circuit die stack of claim 5, wherein the integrated passive device is a deep trench capacitor, or a Metal-Insulator-Metal (MIM) capacitor.

7. The integrated circuit die stack of claim 6, wherein the routing connection is configured to carry data signals.

8. The integrated circuit die stack of claim 1, wherein the bridge die comprises a through silicon via.

9. The integrated circuit die stack of claim 1, further comprising a tier-two integrated circuit die disposed at the second tier, wherein the tier-two integrated die of the second tier is entirely mounted on a top surface of a tier-one integrated circuit die.

10. The integrated circuit die stack of claim 9, further comprising a filler die disposed in a third tier of the integrated circuit die stack, the filler die not electrically connected to the tier-two integrated circuit die in the second tier.

11. The integrated circuit die stack of claim 10, further comprising:
a stiffener surrounding the integrated circuit die stack, and
a cover coupled to the stiffener and the filler die.

12. An integrated circuit die package assembly comprising:
a package substrate; and
an integrated circuit die stack disposed above the package substrate, the integrated circuit die stack comprising:
a first integrated circuit die and a second integrated die disposed at a first tier of the integrated circuit die stack; and
a bridge die disposed at a second tier that is stacked vertically above the first tier, the bridge die having a routing connection coupled with both the first integrated circuit die and the second integrated circuit die, the bridge die including an integrated passive device coupled with the routing connection.

13. The integrated circuit die package assembly of claim 12, wherein integrated passive device is one of a capacitor, an inductor, a resistor, a sensor, a transducer, a circuit protection device, a piezoelectric device, a resonator, or a switch.

14. The integrated circuit die package assembly of claim 13, wherein the routing connection is coupled by a plurality of hybrid bonds of the first and second integrated circuit dice.

15. The integrated circuit die package assembly of claim 14, wherein a pitch of the hybrid bonds is less than 10 μm.

16. The integrated circuit die package assembly of claim 12, the routing connection is defined by a redistribution layer (RDL) formed on a substrate.

17. The integrated circuit die package assembly of claim 16, wherein the integrated passive device is a deep trench capacitor, or a Metal-Insulator-Metal (MIM) capacitor.

18. The integrated circuit die package assembly of claim 14, wherein the routing connection is configured to carry data signals.

19. The integrated circuit die package assembly of claim 12, wherein the first and second integrated circuit dice of the first tier are mounted on an interposer or a package substrate.

20. A method for manufacturing an integrated circuit die stack comprising a plurality of tiers of integrated circuit dice, the method comprising:
arranging a bridge die of a second tier on top of two integrated circuit dice of a first tier, the bridge die comprising an integrated passive device coupled with a routing connection;
forming an integrated circuit die stack by connecting the two integrated circuit dice of the first tier via the routing connection of the bridge die of the second tier; and
mounting the integrated circuit die stack on a package substrate.
